(19) United States
(12) Patent Application Publication
(10) Pub. No.: US 2021/0089149 A1
(43) Pub. Date: Mar. 25, 2021

(54) TOUCH SENSOR CONFIGURATION FOR A RADIAL CAPACITIVE SLIDER

(71) Applicant: NVIDIA Corporation, Santa Clara, CA (US)

(72) Inventors: Ryan Albright, Beaverton, OR (US); Ben Goska, Portland, OR (US)

(21) Appl. No.: 16/578,103

(22) Filed: Sep. 20, 2019

(51) Int. Cl. G06F 3/044; G01R 27/26; H03K 17/955

(52) U.S. Cl. CPC G06F 3/044; H03K 2217/960705; H03K 17/955; G01R 27/2605

(57) ABSTRACT

Radial capacitive sliders on touch enabled devices are physical end-effectors that provide a circular sliding control for a user to manipulate in order to provide input (e.g. menu and/or volume control) to the mobile device. They are traditionally configured to include a plurality of capacitive touch sensors that sense the user's contact with the radial capacitive slider, which is then signaled for use in determining an intended input of the user. The present disclosure provides a touch sensor configuration for radial capacitive sliders that requires less capacitive touch sensors than past configurations while still providing accurate touch sensing to enable correct response by the mobile device.

### TECHNICAL FIELD

The present disclosure relates to radial capacitive sliders.

### BACKGROUND

Radial capacitive sliders on touch enabled devices such as that used on the iPod Classic®, are physical buttons that provide a circular sliding control for a user to manipulate in order to provide input (e.g. menu and/or volume control) to the mobile device. They are traditionally configured to include a plurality of capacitive touch sensors that sense the user's contact with the radial capacitive slider, which is then signaled for use in determining an intended input of the user.

FIG. 1 shows a traditional configuration of a radial capacitive slider 100. As shown, the touch sensors 102A-N are configured as trapezoids linked together to form a ring having an inner diameter I and a larger outer diameter O. Other past configurations have placed the touch sensors in an X/Y grid, similar to a touch pad. In either configuration, to calculate the position of the user's touch on the radial capacitive slider, relative signal levels on adjacent capacitive touch sensors are used. In particular, as the user slides his finger around the radial capacitive slider, relative signal levels of the capacitive touch sensors are determined in order to calculate the position of the user's touch.

Accordingly, when a user's touch overlaps two or more capacitive touch sensors, the position of the user's touch can more accurately be determined, and thus linear position response with respect to some angular position θ will be provided. To provide this accuracy using the trapezoid or X/Y touch sensor configurations mentioned above, the radial capacitive slider requires numerous small touch sensors in order to ensure the user's touch overlaps two or more capacitive touch sensors for numerous given positions on the radial capacitive slider. However, requiring numerous touch sensors to ensure accuracy in turn requires numerous corresponding input/output (I/O) connections, thus increasing manufacturing cost and required processing resources utilized to process the signals output by the touch sensors.

There is a need for addressing these issues and/or other issues associated with the prior art.

### SUMMARY

A touch sensor configuration for a radial capacitive slider is provided. The radial capacitive slider includes a plurality of capacitive touch sensors that form a ring having an outer diameter and an inner diameter, wherein the outer diameter is larger than the inner diameter. Further, each slice of the ring includes at least a portion of each of two or more capacitive touch sensors of the plurality of capacitive touch sensors.

### BRIEF DESCRIPTION OF THE DRAWINGS

FIG. 1 illustrates a touch sensor configuration for a radial capacitive slider, in accordance with the prior art.

FIGS. 2A-B illustrate a spiral touch sensor configuration for a radial capacitive slider, in accordance with an embodiment.

FIGS. 3A-B illustrate a chevron touch sensor configuration for a radial capacitive slider, in accordance with an embodiment.

FIG. 4 illustrates area coverage per touch position for a radial capacitive slider configured in accordance with FIG. 1.

FIG. 5 illustrates that a spiral shape is formed for a curve having a linear area under it with respect to θ, in accordance with an embodiment.

FIG. 6 illustrates a 4 node quadratic pattern for the radial capacitive slider of FIGS. 2A-B.

FIG. 7 illustrates a 4 node polar chevron pattern for the radial capacitive slider of FIGS. 3A-B.

FIG. 8 illustrates area coverage per touch position for a radial capacitive slider configured in accordance with FIGS. 2A-B.

FIG. 9 illustrates area coverage per touch position for a radial capacitive slider configured in accordance with FIGS. 3A-B.

FIG. 10 illustrates a device having the radial capacitive slider of FIGS. 2A-B or 3A-B, in accordance with an embodiment.

### DETAILED DESCRIPTION

Radial capacitive sliders on touch enabled devices are end-effectors that provide a circular sliding control for a user to manipulate in order to provide input (e.g. menu and/or volume control) to the mobile device. They are traditionally configured to include a plurality of capacitive touch sensors that sense a user's contact, which is then signaled for use in determining an intended input of the user.

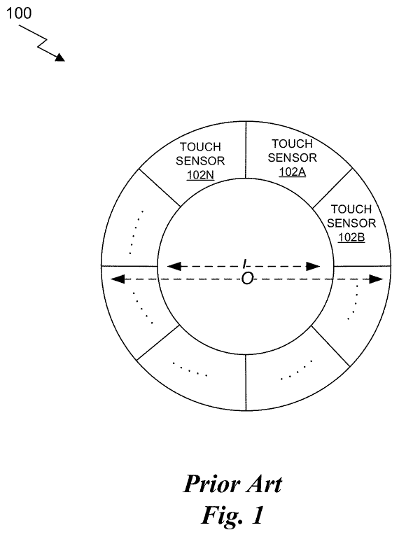

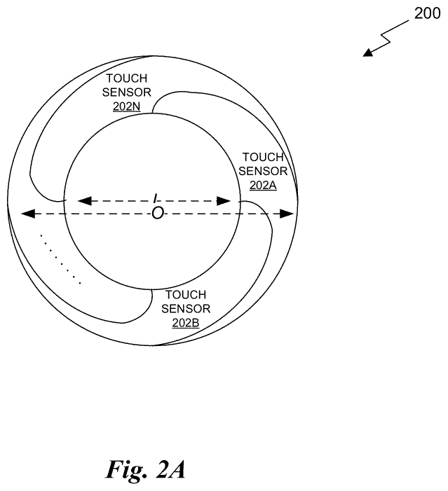

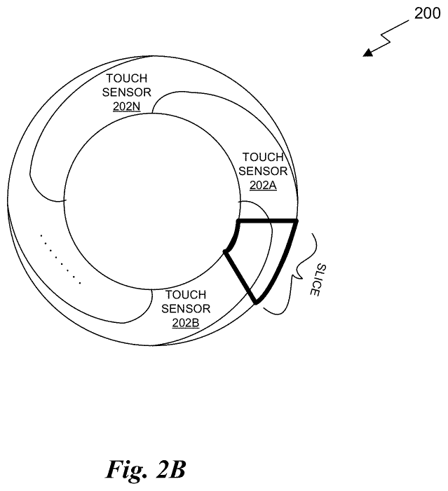

The radial capacitive slider described with respect to the following embodiments is a ring shape having an outer diameter O that is larger than its inner diameter I, similar to Prior Art FIG. 1. The ring is formed by a plurality of physically adjacent capacitive touch sensors, as shown in each of the embodiments described below for FIGS. 2A-B and 3A-B.

In the context of the present description, the capacitive touch sensors refer to hardware devices that detect touch by the user. Unlike a physical button requiring sufficient force to depress the button, for example, the capacitive touch sensors are typically more sensitive, and may be able to respond differently to different kinds of touch, such as tapping, swiping, etc. Each user touch that a touch sensor detects results in a signal being sent to a processing unit and/or software that processes the signal to determine the intended input of the user and to respond accordingly.

Generally, a capacitive touch sensor includes a sensor electrode that is connected to a measurement circuit where the capacitance is measured periodically. The output capacitance will increase if a conductive object (e.g. user's finger) touches or approaches the sensor electrode. The measurement circuit will detect the change in the capacitance and convert it into the aforementioned signal.

For a radial capacitive slider, position of the user's touch on the slider is calculated using relative signal levels on adjacent capacitive touch sensors. In particular, as the user slides his finger around the radial capacitive slider, relative signal levels of the capacitive touch sensors are determined in order to calculate the position of the user's touch at any given moment in time. Accordingly, when a user's touch overlaps two or more capacitive touch sensors, the position of the user's touch can more accurately be determined, and thus linear position response with respect to some angular position θ will be provided.

The capacitive touch sensor configurations of the embodiments described below with respect to FIGS. 2A-B and 3A-B guarantee that at least two capacitive touch sensors are activated for any given slice of the radial capacitive slider touched by a user to provide accurate touch sensing and thus enable correct response by the mobile device, while requiring less capacitive touch sensors than past configurations.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

FIGS. 2A-B illustrate a spiral touch sensor configuration for a radial capacitive slider 200, in accordance with an embodiment. As shown in FIG. 2A, the radial capacitive slider 200 is a ring shape having an outer diameter O that is larger than its inner diameter I. The ring is formed by a plurality of capacitive touch sensors 202A-N, which include at least 3 capacitive touch sensors.

The capacitive touch sensors 202A-N each include an area (A) configured in a spiral or semi-spiral shape, and at least two of the capacitive touch sensors 202A-N will overlap for any given slice (i.e. curved trapezoid) of the radial capacitive slider 200 (see FIG. 2B). The area A for each capacitive touch sensor 202A-N may be wider (top to bottom) at a head end (top end) than at a tail end (bottom end). Thus, the area A for each capacitive touch sensor 202A-N may taper off from the head end to the tail end.

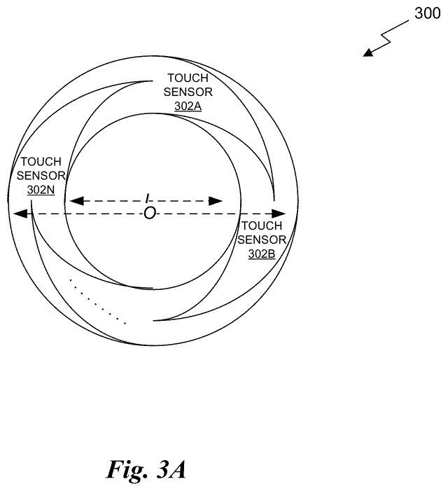

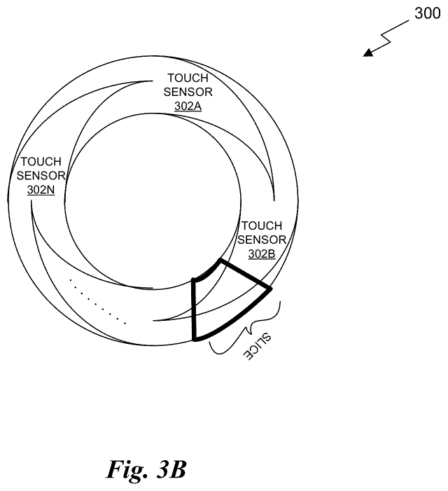

FIGS. 3A-B illustrate a chevron spiral touch sensor configuration for a radial capacitive slider, in accordance with an embodiment. As shown in FIG. 3A, the radial capacitive slider 300 is a ring shape having an outer diameter O that is larger than its inner diameter I. The ring is formed by a plurality of capacitive touch sensors 302A-N, which include at least 3 capacitive touch sensors.

The capacitive touch sensors 302A-N each include an area (A) configured in chevron or semi-chevron shape, and at least two of the capacitive touch sensors 302A-N will overlap for any given slice (i.e. curved trapezoid) of the radial capacitive slider 300 (see FIG. 3B). The area A for each capacitive touch sensor 302A-N may be explained as being wider (top to bottom) at a head end (top end) than at a tail end (bottom end), but for adjacent capacitive touch sensors, the narrowing tail end of one capacitive touch sensor (e.g. 302A) may “cut” into the head end of another capacitive touch sensor (e.g. 302B).

Position Calculation for a Radial Capacitive Slider

When doing centroid (position) calculation of signals on a radial capacitive slider, the centroid is effectively calculated using relative signal levels on adjacent nodes (also referred to as capacitive touch sensors). Equation 1 shows one theorem for performing centroid calculation.

$$Local Signal = ( ( {N}_{max} - 0.5 ) + \frac{{S}_{x + 1} - {S}_{x - 1}}{{S}_{x + 1} + {S}_{x o} + {S}_{x - 1}} ) \\ Scalar = \frac{Resolution}{N} \\ Centroid = ( Local Signal \cdot Scalar ) \% Resolution \\ Where \text{:} \\ {N}_{max} = node index with max signal \\ {S}_{x 0} = Signal of sensor {N}_{max} \\ N = \# nodes in design \\ Note \text{:} Special consideration is required if the node with max signal is the lowest or highest index node . {S}_{x + 1} = {S}_{0} if {N}_{max} = N - 1 and {S}_{x - 1} = {S}_{max} if {N}_{max} = 0 \qquad Equation 1$$

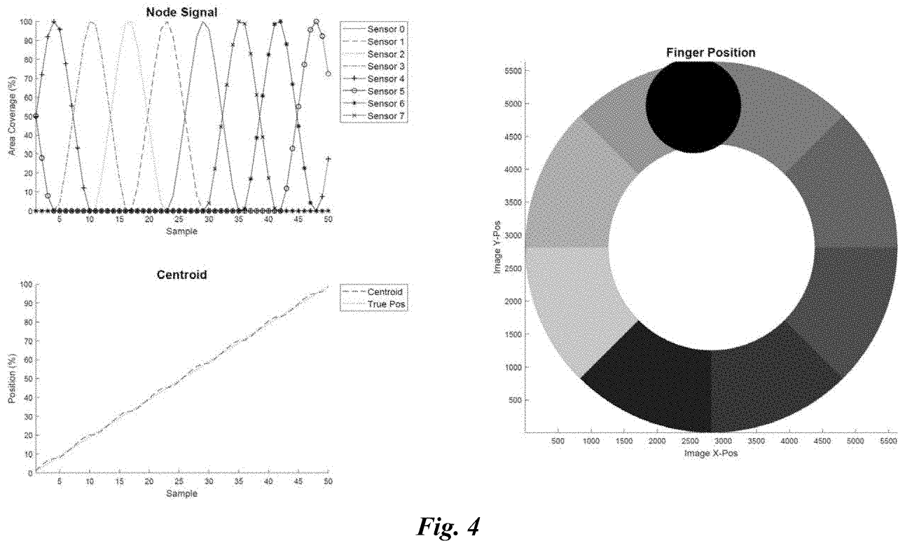

Knowing how to accurately calculate position, the response when moving a finger across a standard trapezoidal based radial slider can be examined. A simulator was written that moves a finger represented by a circle across a path and plots the signal and centroid position across this path. FIG. 4 shows an 8 node standard trapezoidal radial slider (e.g. in accordance with the prior art configuration of FIG. 1) and results of the above described simulation. In this application, signal strength of each node is determined by finite element analysis.

Going back to these first principles, to solve for some curve that has linear area under it with respect to θ, then that shape is defined by Equation 2.

$$c \cdot θ = \frac{d}{d θ} \frac{1}{2} {\int }_{0}^{2 π} {f ( θ )}^{2} d θ \\ f ( θ ) = \sqrt{2 \cdot c \cdot θ} \qquad Equation 2$$

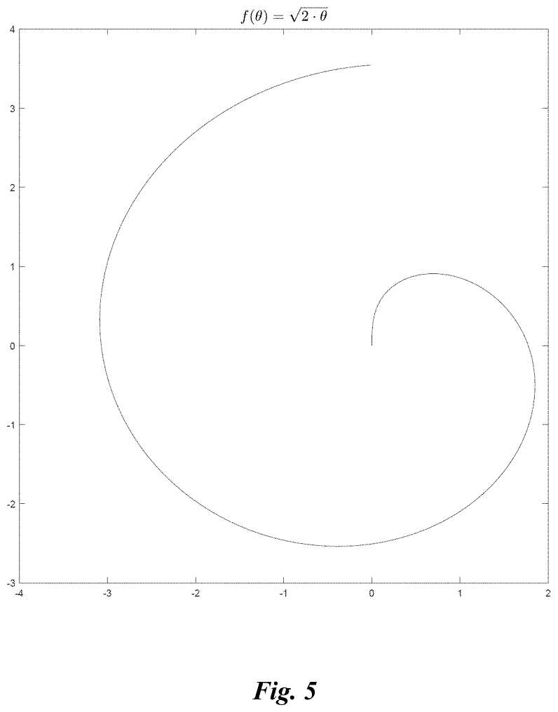

This shape has the general form of a spiral as seen in FIG. 5. If we apply this curve to represent a sensor node, we can apply it to the standard radial ring pattern with two diameters (Dᵢₙₙₑᵣ & Dₒᵤₜₑᵣ) in accordance with Equation 3.

$$n = current node \\ N = total \# nodes \\ ρ = \sqrt{Θ ( n ) \cdot N \cdot \frac{{( \frac{λ}{2} \cdot ( {D}_{outer} - {D}_{inner} ) )}^{2}}{2 π}} + \frac{{D}_{inner}}{2} \\ Θ ( n , θ ) = θ - ( n \cdot \frac{2 π}{N} ) \\ f ( n , θ ) = \sqrt{\frac{( 2 π \cdot N \cdot θ - n ) \cdot {( {D}_{outer} - {D}_{inner} )}^{2}}{8 π}} + \frac{{D}_{inner}}{2} \qquad Equation 3$$

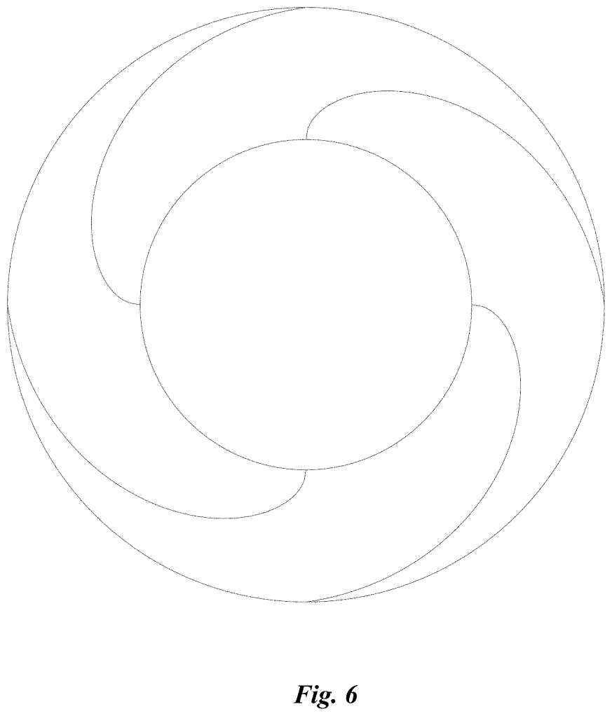

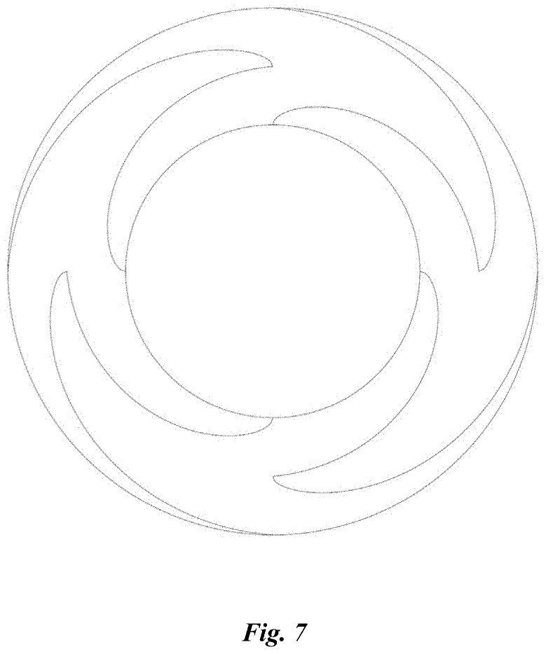

Example of the application of Equation 3 could be shown for N=4, Dᵢₙₙₑᵣ=30, and Dₒᵤₜₑᵣ=54, as shown in FIG. 6. As shown, the area changes linearly with respect to θ with this pattern. The same principle can also be applied in the opposite direction in parallel to achieve more of a “chevron” type pattern (see FIG. 7), using Equation 4 where f₁ and f₂ are the two paths for plotting.

$$n = current node \\ N = total \# nodes \\ {ρ}_{1} = \sqrt{Θ ( n ) \cdot N \cdot \frac{{( \frac{1}{2} \cdot ( {D}_{outer} - {D}_{inner} ) )}^{2}}{4 π}} + \frac{{D}_{inner}}{2} \\ {ρ}_{2} = \sqrt{Θ ( n ) \cdot N \cdot \frac{{( \frac{1}{2} \cdot ( {D}_{outer} \cdot {D}_{inner} ) )}^{2}}{4 π}} + \frac{( {D}_{outer} + {D}_{inner} )}{4} \\ Θ ( n , θ ) = θ - ( n \cdot \frac{2 π}{N} ) \\ {f}_{1} ( n , θ ) = \sqrt{\frac{( 2 π \cdot N \cdot θ - n ) \cdot {( {D}_{outer} - {D}_{inner} )}^{2}}{8 π}} + \frac{{D}_{inner}}{2} \\ {f}_{2} ( n , θ ) = \sqrt{\frac{( 2 π \cdot N \cdot θ - n ) \cdot {( {D}_{outer} - {D}_{inner} )}^{2}}{8 π}} + \frac{( {D}_{outer} + {D}_{inner} )}{4} \qquad Equation 4$$

An example of the application of this could be shown for N=4, Dᵢₙₙₑᵣ=30, and Dₒᵤₜₑᵣ=54, as shown in FIG. 7 where Blue is the first path f₁ and Red is the second path f₂.

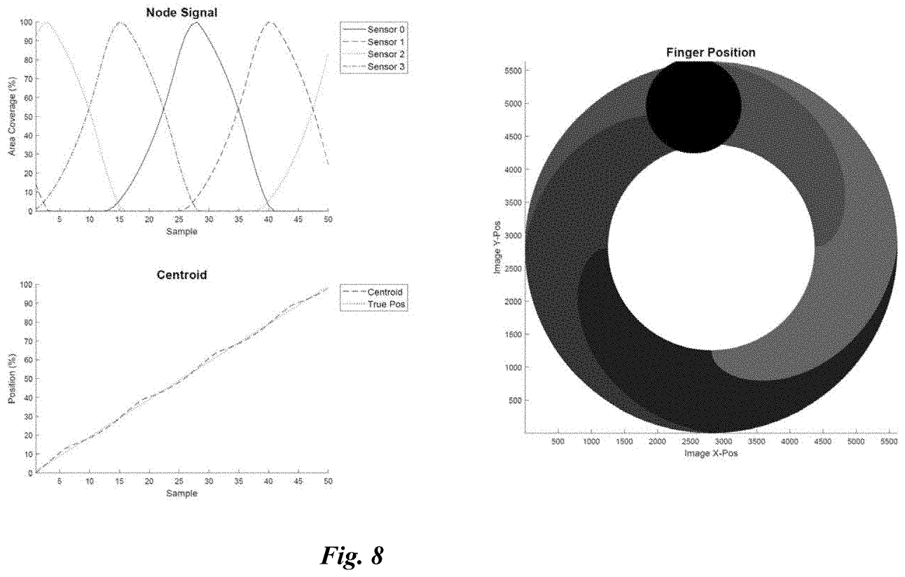

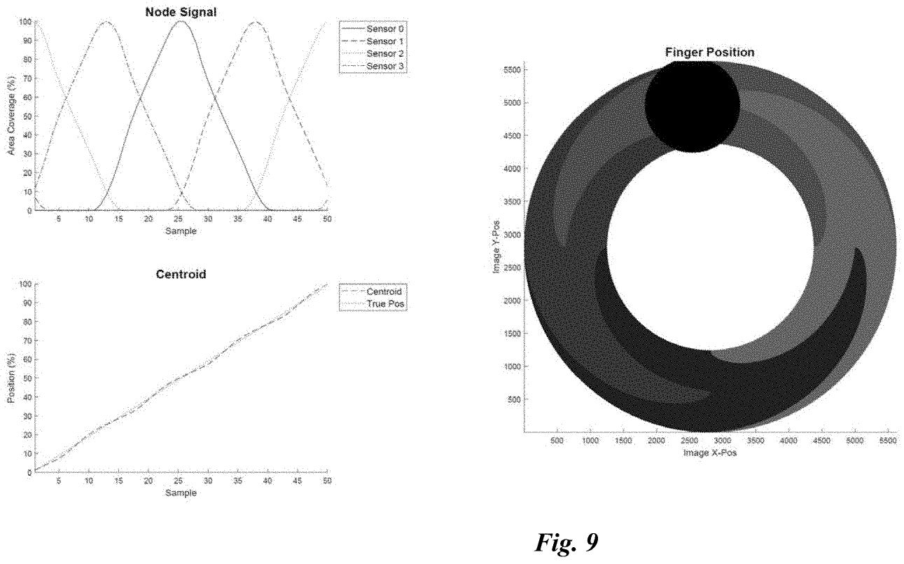

An example of the application of the linear pattern associated with the configuration of FIG. 6 could be shown for N=4 can be seen in FIG. 8 (having the same diameter circles as trapeziodal pattern in FIG. 4). An example of the application of the polar chevrons associated with the configuration of FIG. 7 with the number of nodes N=4 can be seen in FIG. 9. Both FIGS. 8 and 9 show a linear area change with respect to θ. In accordance with the descriptions and Figures above, and going back to the first principles mentioned above, a radial capacitive slider is provided that is more linear and requires less inputs than (e.g. half the inputs of) the radial capacitive sliders of the prior art such as shown in FIG. 1.

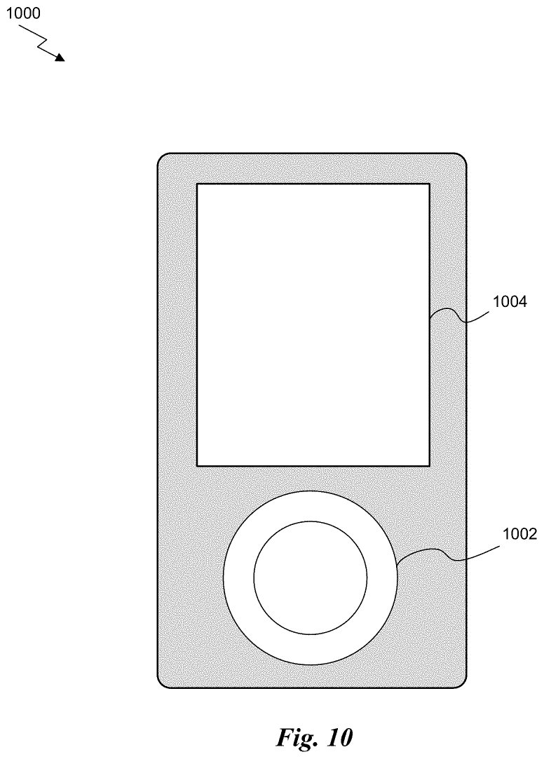

FIG. 10 illustrates a device 1000 having the radial capacitive slider of FIGS. 2A-B or 3A-B, in accordance with an embodiment. For example, the device 1000 may be a mobile device such as a tablet, media player, touch screen, automotive interface, remote control, game controller, mouse/keyboard or similar, headphones, turn-table, radial encoder, etc. Of course, it should be noted that the device 1000 may be any type of device having a radial capacitive slider.

As shown, the device 1000 includes the radial capacitive slider 1002 and a display 1004. The radial capacitive slider 1002 may be manipulated (i.e. touched) by a user to control output of the display 1004, such as to make a menu selection on the display, or to control other features of the device 1000 (e.g. volume control).

As described above with reference to FIGS. 2A-B or 3A-B, the radial capacitive slider 1002 includes a plurality of capacitive touch sensors forming a ring having an outer diameter that is larger than an inner diameter. The capacitive touch sensors are configured within the ring so that each slice of the ring includes at least a portion of a capacitive touch sensor and at least one other capacitive touch sensor. This configuration guarantees that at least two capacitive touch sensors are activated for any given slice of the radial capacitive slider touched by a user.

The radial capacitive slider 1002 also includes a measurement circuit configured to periodically measure capacitance of each of the capacitive touch sensors and to output signals based on the measurements. In one embodiment, each of the capacitive touch sensors includes a sensor electrode that is connected to the measurement circuit where the capacitance of the sensor electrode is measured periodically. For any position of a user's finger on the radial capacitive slider 1002, two or more of the capacitive touch sensors will sense the user's touch and a signal will be provided for use in determining a position of the user's finger on the radial capacitive slider.

The device 1000 further includes a processor (not shown). The processor receives the signals from the radial capacitive slider 1002 and processes the signals to calculate a position of the user's touch on the radial capacitive slider 1002 using relative signal levels on adjacent capacitive touch sensors, and thus to determine an intended input of the user. Based on the intended input determined by the processor, the processor can cause one or more actions to be performed by the device 1000, such as a change to an interface output by the display 1004, a change to a volume of sound output by the device 1000, a change to content or other media output by the device 1000, etc.

1. A radial capacitive slider, comprising:
a plurality of capacitive touch sensors that form a ring having an outer diameter and an inner diameter, wherein the outer diameter is larger than the inner diameter;
wherein each capacitive touch sensor of the plurality of capacitive touch sensors is shaped as a portion of a spiral or a chevron, and
wherein the plurality of capacitive touch sensors are positioned such that any sliced portion of the ring includes at least a portion of each of two adjacent capacitive touch sensors of the plurality of capacitive touch sensors.

2. The radial capacitive slider of claim 1, wherein each capacitive touch sensor of the plurality of capacitive touch sensors is a hardware device that detects touch by a user.

3. The radial capacitive slider of claim 2, wherein each capacitive touch sensor of the plurality of capacitive touch sensors includes a sensor electrode that is connected to a measurement circuit where capacitance of the sensor electrode is measured periodically.

4. The radial capacitive slider of claim 3, wherein the capacitance increases when the user touches the sensor electrode.

5. The radial capacitive slider of claim 4, wherein the measurement circuit detects a change in the capacitance and converts the change into a signal.

6. The radial capacitive slider of claim 5, wherein the signal is sent to a processing unit to determine an intended input of the user.

7. The radial capacitive slider of claim 6, wherein a position of the user's touch on the radial capacitive slider is calculated using relative signal levels on adjacent capacitive touch sensors of the plurality of capacitive touch sensors.

8. The radial capacitive slider of claim 7, wherein linear position response is provided for each angular position θ.

9. The radial capacitive slider of claim 1, wherein the two capacitive touch sensors are adjacent.

10. The radial capacitive slider of claim 1, wherein the plurality of capacitive touch sensors includes at least three capacitive touch sensors.

11. The radial capacitive slider of claim 1, wherein each capacitive touch sensor of the plurality of capacitive touch sensors is shaped as the spiral.

12. The radial capacitive slider of claim 1, wherein each capacitive touch sensor of the plurality of capacitive touch sensors is shaped as the chevron.

13. The radial capacitive slider of claim 1, wherein for any position of a user's finger on the radial capacitive slider, two capacitive touch sensors of the plurality of capacitive touch sensors will sense the user's touch and a signal will be provided for use in determining a position of the user's finger on the radial capacitive slider.

14. A device, comprising:
a radial capacitive slider including:
a plurality of capacitive touch sensors forming a ring having an outer diameter that is larger than an inner diameter,
wherein each capacitive touch sensor of the plurality of capacitive touch sensors is shaped as a portion of a spiral or a chevron, and
wherein the plurality of capacitive touch sensors are positioned such that any sliced portion of the ring includes at least a portion of each of two adjacent capacitive touch sensors of the plurality of capacitive touch sensors, and
a measurement circuit configured to periodically measure capacitance of each capacitive touch sensor of the plurality of capacitive touch sensors and output signals based on the measurements; and
a processor configured to:
receive the signals, and
process the signals to determine an intended input.

15. The device of claim 14, wherein each capacitive touch sensor of the plurality of capacitive touch sensors includes a sensor electrode that is connected to the measurement circuit where the capacitance of the sensor electrode is measured periodically.

16. The device of claim 14, wherein the processor calculates a position of a user's touch on the radial capacitive slider using relative signal levels on adjacent capacitive touch sensors of the plurality of capacitive touch sensors.

17. The device of claim 14, wherein the plurality of capacitive touch sensors includes at least three capacitive touch sensors.

18. The device of claim 14, wherein each capacitive touch sensor of the plurality of capacitive touch sensors is shaped as the spiral.

19. The device of claim 14, wherein each capacitive touch sensor of the plurality of capacitive touch sensors is shaped as the chevron.

20. The device of claim 14, wherein for any position of a user's finger on the radial capacitive slider, two capacitive touch sensors of the plurality of capacitive touch sensors will sense the user's touch and a signal will be provided for use in determining a position of the user's finger on the radial capacitive slider.
